(19) United States
(12) Patent Application Publication
(10) Pub. No.: US 2024/0186422 A1
(43) Pub. Date: Jun. 6, 2024

(54) TRANSISTOR AND DISPLAY PANEL INCLUDING SAME

(71) Applicants: Samsung Display Co., Ltd., Yongin-si (KR); Industry-University Cooperation Foundation Hanyang University ERICA CAMPUS, Ansansi (KR)

(72) Inventors: JOON SEOK PARK, Yongin-si (KR); Saeroonter OH, Ansansi (KR); Su Hyun KIM, Ansansi (KR); Taeho LEE, Ansansi (KR); MYOUNGHWA KIM, Yongin-si (KR); JUN HYUNG LIM, Yongin-si (KR)

(21) Appl. No.: 18/242,005

(22) Filed: Sep. 5, 2023

(30) Foreign Application Priority Data
Dec. 2, 2022 (KR) 10-2022-0166919

(51) Int. Cl. H01L 29/786; H10K 59/121

(52) U.S. Cl. CPC H01L 29/7869; H10K 59/1213

(57) ABSTRACT

Provided is a transistor including a first electrode, an active layer disposed under the first electrode and having a hole pattern with at least one hole in the source region, a drain region, and an active region overlapping the first electrode, and a second electrode disposed under the active layer. At least one of the first electrode and the second electrode overlaps the hole pattern. This way, the area of the transistor may be reduced, thereby achieving a display panel having a narrow bezel and reducing parasitic capacitance.

### CROSS-REFERENCE TO RELATED APPLICATIONS

This U.S. non-provisional patent application claims priority under 35 U.S.C. § 119 of Korean Patent Application No. 10-2022-0166919 filed on Dec. 2, 2022, the entire content of which is hereby incorporated by reference.

### BACKGROUND

The present disclosure herein relates to a transistor and a display panel including the same, and more particularly, to a transistor having a double-gate structure and a display panel including the same.

Display panels are used for various multimedia apparatuses such as televisions, portable phones, tablet computers, and game consoles in order to provide image information to users. A display panel includes light-emitting elements and a pixel circuit for driving the light-emitting elements.

The display panel includes a gate driving circuit for providing signals to the pixel circuit. The light emission of the light-emitting elements is controlled by the signals output from the gate driving circuit.

### SUMMARY

The present disclosure provides a transistor having a double-gate structure with reduced parasitic capacitance.

The present disclosure also provides a display panel having a narrow bezel by including a transistor having a double-gate structure.

An embodiment of the inventive concept provides a transistor including a first electrode, an active layer disposed under the first electrode and including a source region, a drain region, and an active region overlapping the first electrode on a plane, and a second electrode disposed under the active layer and overlapping at least a portion of the active layer on a plane, wherein the active layer includes a hole pattern, and the hole pattern overlaps at least a portion of the source region and a portion of the drain region on a plane.

In an embodiment, the drain region, the active region, and the source region may be sequentially arranged along a first direction, and the second electrode may have a length greater than the first electrode in the first direction.

In an embodiment, the hole pattern may partially overlap the first electrode.

In an embodiment, the drain region, the active region, and the source region may be sequentially arranged along a first direction, the length of the first electrode in the first direction may be about 4 μm to about 10 μm, and an overlap length of the hole pattern overlapping the first electrode is equal to or less than about 4 μm measured in the first direction.

In an embodiment, the overlap length of the hole pattern overlapping the first electrode may be equal to or less than about 1 μm.

In an embodiment, the hole pattern may include a plurality of holes, and the ratio of the sum of the widths of the plurality of holes to the width of the active layer may be no more than about 40%.

In an embodiment, the hole pattern is in the part of the active layer that does not overlap the first electrode.

In an embodiment, the hole pattern may include a plurality of holes, and the ratio of the sum of the widths of the plurality of holes to the width of the active layer may be no more than about 80%.

In an embodiment, the hole pattern may partially overlap the second electrode.

In an embodiment, the hole pattern may overlap the second electrode.

In an embodiment, the first electrode and the second electrode may be electrically connected to each other and receive a same voltage.

In an embodiment, the active layer may include an oxide semiconductor.

In an embodiment of the inventive concept, a display panel includes a base layer, a circuit layer disposed on the base layer and including a gate driving circuit, and a light-emitting layer disposed on the circuit layer. The gate driving circuit includes a plurality of transistors, and at least one of the plurality of transistors includes a first electrode, an active layer disposed under the first electrode and including a hole pattern, and a second electrode disposed under the active layer and overlapping at least a portion of the active layer on a plane.

In an embodiment, the active layer may include a source region, a drain region, and an active region overlapping the first electrode on a plane, the drain region, the active region, and the source region may be sequentially arranged along a first direction, and the second electrode may have a length greater than the first electrode in the first direction.

In an embodiment, the hole pattern may overlap at least a portion of the source region and a portion of the drain region on a plane.

In an embodiment, on a plane, one portion of the hole pattern may partially overlap the first electrode.

In an embodiment, the active layer may include a source region, a drain region, and an active region overlapping the first electrode on a plane, the drain region, the active region, and the source region may be sequentially arranged along a first direction, the length of the first electrode in the first direction may be about 4 μm to about 10 μm, and an overlap length of the hole pattern overlapping the first electrode may be equal to or less than about 4 μm measured in the first direction.

In an embodiment, the hole pattern may partially overlap the second electrode.

In an embodiment, the hole pattern may not overlap the first electrode.

In an embodiment, the hole pattern may overlap the second electrode.

In an embodiment, the first electrode and the second electrode may be electrically connected to each other and receive a same voltage.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1A is a perspective view of a display device according to an embodiment of the inventive concept;

FIG. 1B is a cross-sectional view of a display device according to an embodiment of the inventive concept;

FIG. 1C is a plan view of a display panel according to an embodiment of the inventive concept;

FIG. 2 is an equivalent circuit diagram of a pixel according to an embodiment of the inventive concept;

FIG. 3A is an enlarged plan view of a display region according to an embodiment of the inventive concept;

FIG. 3B is a cross-sectional view illustrating a display region of a display device according to an embodiment of the inventive concept;

FIG. 4 is an equivalent circuit diagram of a gate driving circuit according to an embodiment of the inventive concept;

FIG. 5A is a plan view schematically illustrating a transistor according to an embodiment of the inventive concept;

FIG. 5B is a graph showing electron mobility of a transistor according to an embodiment of the inventive concept;

FIG. 6A is a cross-sectional view illustrating a non-display region of a display device according to an embodiment of the inventive concept;

FIG. 6B is a cross-sectional view illustrating a non-display region of a display device according to an embodiment of the inventive concept;

FIG. 7 is a cross-sectional view illustrating a non-display region of a display device according to an embodiment of the inventive concept;

FIG. 8 is a plan view schematically illustrating a transistor according to an embodiment of the inventive concept;

FIG. 9A is a plan view schematically illustrating a transistor according to an embodiment of the inventive concept;

FIG. 9B is a graph showing electron mobility of a transistor according to an embodiment of the inventive concept;

FIG. 10 is a plan view schematically illustrating a transistor according to an embodiment of the inventive concept;

FIG. 11 is a perspective view of a display device according to an embodiment of the inventive concept; and

FIG. 12 is a cross-sectional view illustrating a display region of a display device according to an embodiment of the inventive concept.

### DETAILED DESCRIPTION

Embodiments of the inventive concept will be described below with reference to the accompanying drawings. The inventive concept may, however, be embodied in forms that are different from what is depicted in the drawings and the disclosure should not be limited to the embodiments set forth herein. Rather, these embodiments are provided so that this disclosure will be thorough and complete, and will fully convey the scope of the inventive concept to those skilled in the art.

In this specification, it will be understood that when an element (or a region, a layer, a portion, or the like) is referred to as being “on”, “connected to” or “coupled to” another element, it may be directly disposed on, connected or coupled to the other element, or intervening elements may be disposed therebetween.

Meanwhile, in this specification, when an element, such as a layer, a film, a region, or a substrate, is referred to as being “directly on,” “directly connected to” or “directly coupled to” another element, there are no intervening elements, such as a layer, a film, a region, or a substrate, present therebetween. For example, when an element is referred to as being “directly on,” two layers or members are disposed without an additional member, such as an adhesion member, being used therebetween.

Like reference numerals or symbols refer to like elements throughout. In the drawings, the thickness, the ratio, and the size of the element are exaggerated for effective description of the technical contents.

As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the inventive concept. Similarly, a second element, component, region, layer or section may be termed a first element, component, region, layer or section. As used herein, the singular forms, “a”, “an” and “the” are intended to include the plural forms as well, unless the context clearly indicates otherwise.

Also, terms of “below”, “on lower side”, “above”, “on upper side”, or the like may be used to describe the relationships of the elements illustrated in the drawings. These terms have relative concepts and are described on the basis of the directions indicated in the drawings. In this specification, the term “disposed on” may indicate a case of being disposed below as well as above any one member.

It will be further understood that the terms “includes” and/or “have”, when used in this specification, specify the presence of stated features, integers, steps, operations, elements, components, and/or groups thereof, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept will be described in detail with reference to the accompanying drawings.

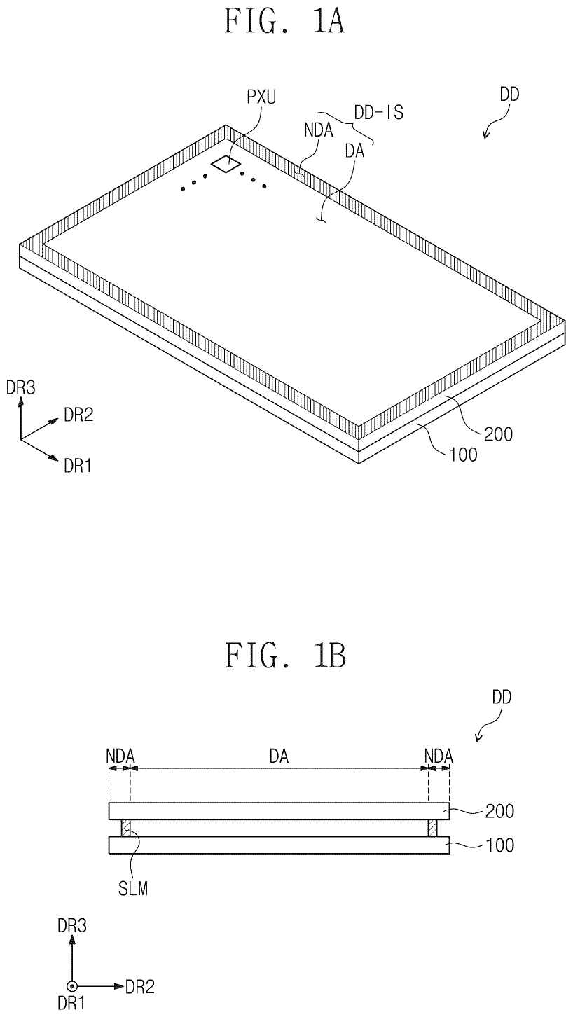

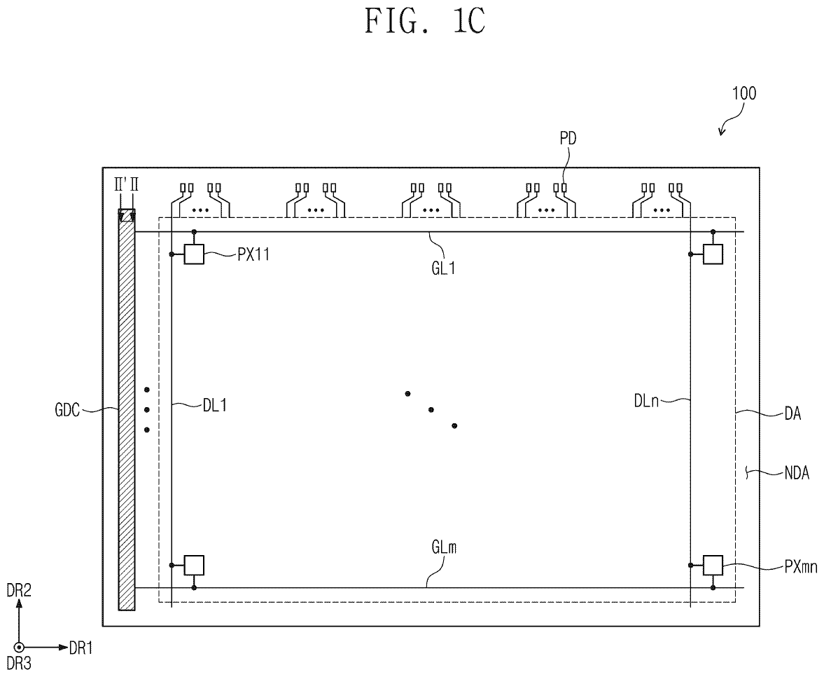

FIG. 1A is a perspective view of a display device DD according to an embodiment of the inventive concept. FIG. 1B is a cross-sectional view of a display device DD according to an embodiment of the inventive concept. FIG. 1C is a plan view of a display panel 100 according to an embodiment of the inventive concept.

Referring to FIG. 1A, a display device DD may display an image through a display surface DD-IS. The display surface DD-IS may be parallel to a surface defined by a first direction DR1 and a second direction DR2. An upper surface of a member disposed on the uppermost side of the display device DD in a third direction DR3 may be defined as the display surface DD-IS.

The normal direction of the display surface DD-IS, which is the thickness direction of the display device DD, may be indicated by the third direction DR3. A front surface (or upper surface) and a rear surface (or lower surface) of each of the layers or units to be described below may be distinguished based on the third direction DR3.

The display device DD may include a display region DA and a non-display region NDA. Unit pixels PXU are disposed in the display region DA, and are not disposed in the non-display region NDA. The non-display region NDA may be defined along the border of the display surface DD-IS. The non-display region NDA may surround the display region DA. According to an embodiment of the inventive concept, the non-display region NDA may be omitted, or disposed only on one side of the display region DA. FIG. 1A exemplarily illustrates a flat display device DD, but the display device DD may have a curved shape, may be foldable or rollable, or may be slidably moved from a housing.

The unit pixels PXU illustrated in FIG. 1A may define pixel rows and pixel columns. The unit pixel PXU, which is a minimum repetition unit, may include at least one pixel. The unit pixel PXU may include a plurality of pixels that provide light of different colors.

Referring to FIG. 1B, the display device DD may include a display panel 100, and a light conversion panel 200 facing the display panel 100 and with a distance therefrom. The display panel 100 may be referred to as a lower display substrate, and the light conversion panel 200 may be referred to as an upper display substrate. A predetermined cell gap may be formed between the display panel 100 and the light conversion panel 200. The cell gap may be maintained by a sealing member SLM that couples the display panel 100 to the light conversion panel 200. The sealing member SLM may include a binder resin, and inorganic fillers mixed in the binder resin. The sealing member SLM may further include other additives. The additives may include an amine-based curing agent and a photo-initiator. The additives may further include a silane-based additive and an acrylic-based additive. The sealing member SLM may also include an inorganic material such as frit.

Referring to FIG. 1B, a display region DA and a non-display region NDA of the display device DD may be defined in each of the display panel 100 and the light conversion panel 200. Hereinafter, the display region DA of the display device DD may refer to the display region DA of each of the display panel 100 and the light conversion panel 200, and the non-display region NDA of the display device DD may refer to the non-display region NDA of each of the display panel 100 and the light conversion panel 200.

FIG. 1C illustrates the relationship of a planar arrangement of signal lines GL1 through GLm, and DL1 through DLn, and pixels PX11 through PXmn. The signal lines GL1 through GLm, and DL1 through DLn may include a plurality of gate lines GL1 through GLm, and a plurality of data lines DL1 through DLn.

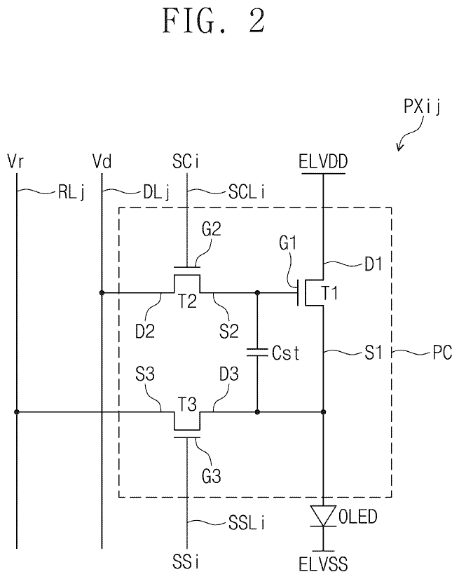

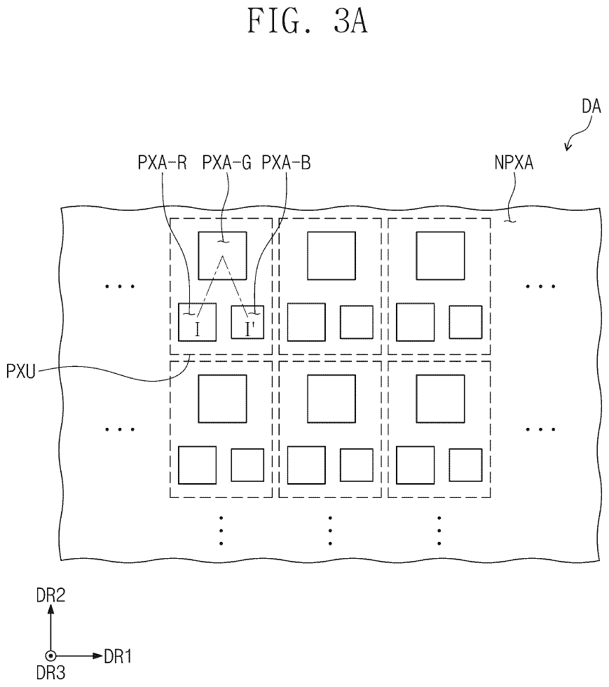

Each of the pixels PX11 through PXmn may be connected to a corresponding gate line among the plurality of gate lines GL1 through GLm, and to a corresponding data line among the plurality of data lines DL1 through DLn. Each of the pixels PX11 through PXmn may include a pixel driving circuit and a light-emitting element. Various types of signal lines may be provided in the display panel 100 according to configurations of the pixel driving circuits of the pixels PX11 through PXmn. For example, each of the gate lines GL1 through GLm may include a corresponding scan line SCLi (see FIG. 2) and a corresponding sensing line SSLi (see FIG. 2).

A gate driving circuit GDC may be integrated into the display panel 100 through an oxide semiconductor gate driver circuit (OSG) process. The gate driving circuit GDC connected to the gate lines GL1 through GLm may be disposed on one side of the non-display region NDA in the first direction DR1. Pads PD connected to the ends of the plurality of data lines DL1 through DLn may be disposed on one side of the non-display region NDA in the second direction DR2.

FIG. 2 is an equivalent circuit diagram of a pixel PXij according to an embodiment of the inventive concept.

FIG. 2 exemplarily illustrates a pixel PXij connected to an ith scan line SCLi, an ith sensing line SSLi, a jth data line DLj, and a jth reference line RLj. The pixel PXij may include a pixel circuit PC and a light-emitting element OLED connected to the pixel circuit PC. The pixel circuit PC may include a plurality of transistors T1, T2, and T3 and a capacitor Cst. The plurality of transistors T1, T2, and T3 may be formed through a low temperature polycrystalline oxide (LTPO) process. Hereinafter, the plurality of transistors T1, T2, and T3 may be described as N-type transistors, but at least one transistor may be configured as a P-type transistor. According to another embodiment of the inventive concept, at least some of the plurality of transistors T1, T2, and T3 may also be formed through a low temperature polycrystalline silicon (LTPS) process.

In this embodiment, it is exemplarily illustrated that the pixel circuit PC includes a first transistor T1, a second transistor T2, a third transistor T3, and a capacitor Cst, but the pixel circuit PC is not limited thereto. The first transistor T1 may be a driving transistor, the second transistor T2 may be a switching transistor, and the third transistor T3 may be a sensing transistor. The pixel circuit PC may further include an additional transistor or capacitor.

The light-emitting element OLED may be an organic light-emitting element or an inorganic light-emitting element including an anode (first electrode) and a cathode (second electrode). The anode of the light-emitting element OLED may receive a first voltage ELVDD through the first transistor T1, and the cathode of the light-emitting element OLED may receive a second voltage ELVSS. The light-emitting element OLED may emit light by receiving the first voltage ELVDD and the second voltage ELVSS.

The first transistor T1 may include a drain region D1 that receives the first voltage ELVDD, a source region S1 connected to the anode of the light-emitting element OLED, and a gate G1 connected to the capacitor Cst. The first transistor T1 may control a driving current, flowing from the first voltage ELVDD through the light-emitting element OLED, in response to a value of voltage stored in the capacitor Cst.

The second transistor T2 may include a drain D2 connected to the jth data line DLj, a source S2 connected to the capacitor Cst, and a gate G2 that receives an ith first scan signal SCi. The jth data line DLj may receive a data voltage Vd. The second transistor T2 may provide the data voltage Vd to the first transistor T1 in response to the ith first scan signal SCi.

The third transistor T3 may include a source S3 connected to the jth reference line RLj, a drain D3 connected to the anode of the light-emitting element OLED, and a gate G3 that receives an ith second scan signal SSi. The jth reference line RLj may receive a reference voltage Vr. The third transistor T3 may initialize the capacitor Cst and the anode of the light-emitting element OLED.

The capacitor Cst may store a voltage corresponding to the difference between the voltage received from the second transistor T2 and the first voltage ELVDD. The capacitor Cst may be connected to the gate G1 of the first transistor T1 and the anode of the light-emitting element OLED.

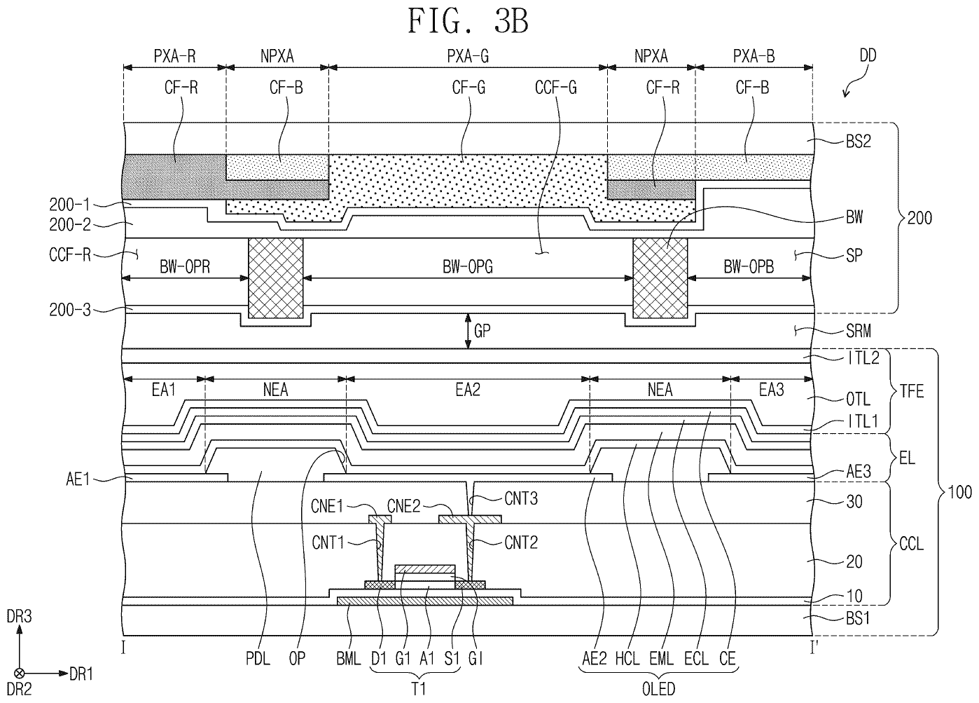

FIG. 3A is an enlarged plan view of a display region DA according to an embodiment of the inventive concept. FIG. 3B is a cross-sectional view illustrating a display region DA of a display device according to an embodiment of the inventive concept. FIG. 3B may be an exemplary cross-sectional view taken along line I-I′ of FIG. 3A.

As illustrated in FIG. 3A, unit pixels PXU may be arranged in a first direction DR1 and a second direction DR2. In an embodiment, the unit pixel PXU may include a first pixel, a second pixel, and a third pixel which emit light of different colors. The first pixel, the second pixel, and the third pixel may emit red light, green light, and blue light, respectively. FIG. 3A illustrates a first pixel region PXA-R, a second pixel region PXA-G, and a third pixel region PXA-B respectively representing the first pixel, the second pixel, and the third pixel. The first pixel region PXA-R may be a region that provides light generated from the first pixel to the outside, the second pixel region PXA-G may be a region that provides light generated from the second pixel to the outside, and the third pixel region PXA-B may be a region that provides light generated from the third pixel to the outside.

A peripheral region NPXA may be disposed surrounding the first pixel region PXA-R, the second pixel region PXA-G, and the third pixel region PXA-B. Alternatively, the peripheral region NPXA may be disposed between the first pixel region PXA-R, the second pixel region PXA-G, and the third pixel region PXA-B. The peripheral region NPXA may set boundaries of the first through third pixel regions PXA-R, PXA-G, and PXA-B, and prevent color mixing between the first through third pixel regions PXA-R, PXA-G, and PXA-B.

Referring to FIG. 3A, the first pixel region PXA-R and the third pixel region PXA-B may be disposed in the same row, and the second pixel region PXA-G may be disposed in a row different from the row where the first pixel region PXA-R and the third pixel region PXA-B are disposed. The second pixel region PXA-G may have the largest area, and the third pixel region PXA-B may have the smallest area, but an embodiment of the inventive concept is not limited thereto. In this embodiment, it is illustrated that the first pixel region PXA-R, the second pixel region PXA-G, and the third pixel region PXA-B substantially have square shapes, but an embodiment of the inventive concept is not limited thereto.

FIG. 3B is a cross-sectional view which mainly illustrates the second pixel region PXA-G, and in which a cross-section of a first transistor T1 is exemplarily illustrated. Stacked structures of the first pixel region PXA-R and the third pixel region PXA-B may also be similar to a stacked structure of the second pixel region PXA-G.

A display panel 100 may include a first base layer BS1, a circuit layer CCL, a light-emitting element layer EL, and a thin-film encapsulation layer TFE. The circuit layer CCL may be disposed on the first base layer BS1. Meanwhile, in this specification, the first base layer BS1 may be referred to as a base layer. The circuit layer CCL may include a plurality of insulation layers, a plurality of conductive layers, and a semiconductor layer. The light-emitting element layer EL may be disposed on the circuit layer CCL. The thin-film encapsulation layer TFE may be disposed on the light-emitting element layer EL, and may seal the light-emitting element layer EL.

The first base layer BS1 may include a glass or synthetic resin film. The synthetic resin layer may include a thermosetting resin. In particular, the synthetic resin layer may be a polyimide-based resin layer, and the material thereof is not particularly limited. The synthetic resin layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, or a perylene-based resin. In addition, the first base layer BS1 may include a glass substrate, a metal substrate, an organic/inorganic composite material substrate, or the like.

A light-blocking pattern BML may be disposed on the first base layer BS1. The light-blocking pattern BML may include metal. A signal line may be disposed on the same layer as the light-blocking pattern BML. A first insulation layer 10 that covers the light-blocking pattern BML may be disposed on the first base layer BS1.

A semiconductor pattern overlapping the light-blocking pattern BML may be disposed on the first insulation layer 10. The semiconductor pattern may include an oxide semiconductor. The oxide semiconductor may include a plurality of regions classified according to whether a metal oxide is reduced or not. A region where the metal oxide is reduced (hereinafter, reduced region) has higher conductivity than a region where the metal oxide is unreduced (hereinafter, unreduced region). The reduced region substantially serves as a signal line or a source/drain of a transistor. The unreduced region is substantially an active region (or semiconductor region, or channel region) of a transistor. In other words, a portion of the semiconductor pattern may be an active region of the transistor, another portion thereof may be a source/drain region, and another portion thereof may be a signal transmission region.

Meanwhile, in this specification, the semiconductor pattern may be referred to as an active layer. In addition, the unreduced region may be referred to as an active region A1 or a channel region, and the reduced region may be referred to as a source region S1 or a drain region D1 according to voltage applied thereto.

The semiconductor pattern may include the source region S1, the active region A1, and the drain region D1.

A gate insulation layer GI may be disposed on the active region A1. The gate insulation layer GI may insulate the active layer and a gate G1, and form the capacitor Cst (see FIG. 2). The gate insulation layer GI may be an inorganic layer.

The gate G1 may be disposed on the gate insulation layer GI. The gate G1 of the first transistor T1 may overlap the active region A1. The gate insulation layer GI may be patterned in correspondence to a shape of the gate G1. Therefore, the gate insulation layer GI may be referred to as a gate insulation pattern.

A second insulation layer 20 may be disposed on the first insulation layer 10. In the second insulation layer 20, contact holes CNT1 and CNT2 that expose the source region S1 and the drain region D1 may be defined. The first insulation layer 10 may be an inorganic layer, and the second insulation layer 20 may be an organic layer.

Connecting electrodes CNE1 and CNE2 are disposed on the second insulation layer 20. A second connecting electrode CNE2 may electrically connect the source region S1 of the first transistor T1 to the drain D3 of the third transistor T3 illustrated in FIG. 2. A first connecting electrode CNE1 electrically connects the drain region D1 of the first transistor T1 to a signal line that receives the first voltage ELVDD illustrated in FIG. 2.

A third insulation layer 30 may be disposed on the second insulation layer 20. An anode AE2 of a light-emitting element OLED may be disposed on the third insulation layer 30. The anode AE2 may be connected to the second connecting electrode CNE2 through a contact hole CNT3 extending through the third insulation layer 30. The third insulation layer 30 may be an organic layer. Meanwhile, the anodes AE1 and AE3 of the first pixel region PXA-R and the third pixel region PXA-B may be disposed on the same layer as the anode AE2 of the second pixel region PXA-G.

A light-emitting element OLED and pixel-defining films PDL may be disposed on the third insulation layer 30. An opening OP of the pixel-defining film PDL may expose at least a portion of the anode AE2. The openings OP of the pixel-defining films PDL may define light-emitting regions EA1, EA2, and EA3 respectively corresponding to the anodes AE1, AE2, and AE3 of the first pixel region PXA-R, the second pixel region PXA-G, and the third pixel region PXA-B. A region, which is between the light-emitting regions EA1, EA2, and EA3, and in which the pixel-defining films PDL are disposed, may be defined as non-light-emitting regions NEA.

A hole control layer HCL may be disposed as a common layer in the light-emitting regions EA1, EA2, and EA3, and the non-light-emitting region NEA. A common layer such as the hole control layer HCL may be disposed overlapping the plurality of unit pixels PXU in the display region DA illustrated in FIG. 3A. The hole control layer HCL may include a hole transport layer and a hole injection layer.

A light-emitting layer EML is disposed as a common layer on the hole control layer HCL. The light-emitting layer EML may be disposed in the light-emitting regions EA1, EA2, and EA3 and the non-light-emitting region NEA. The light-emitting layer EML may generate source light.

An electron control layer ECL is disposed on the light-emitting layer EML. The electron control layer ECL may include an electron transport layer and an electron injection layer. A cathode CE may be disposed on the electron control layer ECL. A thin-film encapsulation layer TFE may be disposed on the cathode CE. The thin-film encapsulation layer TFE may be disposed in common in the plurality of unit pixels PXU of the display region DA illustrated in FIG. 3A. In this embodiment, the thin-film encapsulation layer TFE may directly cover the cathode CE.

The thin-film encapsulation layer TFE may include at least one inorganic layer or at least one organic layer. The thin-film encapsulation layer TFE may include a first inorganic encapsulation layer ITL1, an organic encapsulation layer OTL, and a second inorganic encapsulation layer ITL2 that are stacked in sequence. The organic encapsulation layer OTL may be disposed between the first inorganic encapsulation layer ITL1 and the second inorganic encapsulation layer ITL2. The first inorganic encapsulation layer ITL1 and the second inorganic encapsulation layer ITL2 protect the light-emitting element layer EL from moisture and oxygen, and the organic encapsulation layer OTL protects the light-emitting element layer EL from foreign substances such as dust particles. The first inorganic encapsulation layer ITL1 and the second inorganic encapsulation layer ITL2 may include at least one of silicon nitride, silicon oxynitride, silicon oxide, titanium oxide, or aluminum oxide. The organic encapsulation layer OTL may include a polymer, for example, an acrylic-based organic layer. However, this is an example, and an embodiment of the inventive concept is not limited thereto.

FIG. 3B exemplarily illustrates that the thin-film encapsulation layer TFE includes two inorganic layers and one organic layer, but an embodiment of the inventive concept is not limited thereto. For example, the thin-film encapsulation layer TFE may include three inorganic layers and two organic layers, and in this case, the inorganic layer and the organic layer may be alternately stacked.

A synthetic resin material SRM may be disposed in a cell gap GP between the light conversion panel 200 and the display panel 100. The light conversion panel 200 is coupled to the display panel 100 with the synthetic resin material SRM therebetween, and thus the synthetic resin material SRM is positioned in the cell gap GP. According to an embodiment of the inventive concept, the synthetic resin material SRM may also be omitted.

The light conversion panel 200 may include a second base layer BS2, color filters CF-R, CF-G, and CF-B disposed under the second base layer BS2, light control patterns CCF-R, CCF-G, and SP, partition walls BW, and a plurality of insulation layers 200-1, 200-2, and 200-3. The second base layer BS2 may include a glass or synthetic resin film. The synthetic resin layer may include a thermosetting resin. In particular, the synthetic resin layer may be a polyimide-based resin layer, and the material thereof is not particularly limited.

The color filters CF-R, CF-G, and CF-B may include a first color filter CF-R, a second color filter CF-G, and a third color filter CF-B. The first color filter CF-R may be disposed overlapping the first light-emitting region EA1, the second color filter CF-G may be disposed overlapping the second light-emitting region EA2, and the third color filter CF-B may be disposed overlapping the third light-emitting region EA3. The first color filter CF-R transmits third color-light, and blocks first-color light and second-color light. The second color filter CF-G transmits the second-color light and blocks the first-color light and the third-color light. The third color filter CF-B transmits the first-color light and blocks the second-color light and the third-color light. The second color filter CF-G transmits second source light, but may transmit only light having a partial wavelength range of the wavelength of the second source light, that is, only light having the center wavelength range, in order to increase the purity of color. For the same reason, the third color filter CF-B may transmit only light having a partial wavelength range of the wavelength of first source light, that is, only light having the center wavelength range.

The first color filter CF-R, the second color filter CF-G, and the third color filter CF-B may define the first pixel region PXA-R, the second pixel region PXA-G, the third pixel region PXA-B, and the peripheral region NPXA. A region where at least two color filters among the first color filter CF-R, the second color filter CF-G, and the third color filter CF-B are disposed overlapping may be defined as a peripheral region NPXA. Only the corresponding color filter among the first color filter CF-R, the second color filter CF-G, and the third color filter CF-B is disposed in each of the first pixel region PXA-R, the second pixel region PXA-G, and the third pixel region PXA-B. When a black matrix pattern (not shown) is further disposed, the peripheral region NPXA may be defined as a region where the black matrix is disposed.

A first insulation layer 200-1 may be disposed under the first color filter CF-R, the second color filter CF-G, and the third color filter Cf-B, and cover the first color filter CF-R, the second color filter CF-G, and the third color filter CF-B. A second insulation layer 200-2 may cover the first insulation layer 200-1 and provide a flat surface thereunder. The first insulation layer 200-1 may be an inorganic film, and the second insulation layer 200-2 may be an organic film.

The partition walls BW may be disposed under the second insulation layer 200-2. The partition walls BW may overlap the peripheral region NPXA on a plane. Openings BW-OPR, BW-OPG, and BW-OPB may be defined in the partition walls BW. The openings BW-OPR, BW-OPG, and BW-OPB may correspond respectively to the first pixel region PXA-R, the second pixel region PXA-G, and the third pixel region PXA-B, and correspond respectively to the first light-emitting region EA1, the second light-emitting region EA2, and the third light-emitting region EA3. The term “corresponding” means that two components overlap on a plane, and are not limited to having the same area.

The partition wall BW may include a material having a transmittance of a predetermined value or less. For example, the partition wall BW may include a light-blocking material, and include, for example, a typical black ingredient. The partition wall BW may include a black dye or black pigment mixed in a base resin. For example, the partition wall BW may include at least one of propylene glycol methyl ether acetate, 3-methoxy-n-butyl acetate, acrylate monomer, acrylic monomer, an organic pigment, or acrylate ester.

The light control patterns CCF-R, CCF-G, and SP may include a first light conversion pattern CCF-R, a second light conversion pattern CCF-G, and a transparent resin pattern SP respectively disposed in the openings BW-OPR, BW-OPG, and BW-OPB. The first light conversion pattern CCF-R, the second light conversion pattern CCF-G, and the transparent resin pattern SP may be respectively disposed in the first pixel region PXA-R, the second pixel region PXA-G, and the third pixel region PXA-B.

The first light conversion pattern CCF-R may convert the first source light to the third-color light. The third-color light may be red light. The second light conversion pattern CCF-G may convert the first-color light to the second-color light. The second-color light may be green light.

The transparent resin pattern SP transmits the first-color light and the second-color light without converting the first-color light and the second-color light to light of different colors. The transparent resin pattern SP may include a transparent base resin. The transparent resin pattern SP may further include scattering particles mixed in the base resin. The scattering particles may scatter the first-color light passing through the transparent resin pattern SP and widen the viewing angle of the third pixel region PXA-B.

The first light conversion pattern CCF-R, the second light conversion pattern CCF-G, and the transparent resin pattern SP may each be formed through an inkjet process. The first light conversion pattern CCF-R, the second light conversion pattern CCF-G, and the transparent resin pattern SP may be formed by providing compositions respectively to the spaces defined by the partition walls, for example, the plurality of openings BW-OPR, BW-OPG, and BW-OPB.

The first light conversion pattern CCF-R and the second light conversion pattern CCF-G may include quantum dots. Each of the first light conversion pattern CCF-R and the second light conversion pattern CCF-G may include a base resin, quantum dots, and scattering particles. According to an embodiment of the inventive concept, the scattering particles may be omitted.

The base resin that is a medium where quantum dots or scattering particles are dispersed may include various resin compositions which may be referred to as binders in general. However, an embodiment of the inventive concept is not limited thereto, and in this specification, any medium capable of distributing quantum dots may be referred to as a base resin regardless of the name, additional different function, or material thereof. The base resin may be a polymer resin. For example, the base resin may be an acrylic-based resin, a urethane-based resin, a silicone-based resin, and an epoxy-based resin. The base resin may be a transparent resin.

The scattering particle may be a titanium oxide (TiO₂) particle, a silica-based nanoparticle, or the like. The scattering particle may cause incident light to be scattered and increase the quantity of light provided to the outside. According to an embodiment of the inventive concept, at least one of the first light conversion pattern CCF-R or the second light conversion pattern CCF-G may include no scattering particle.

The quantum dot may convert the wavelength of incident light. The quantum dot, which is a material having a crystal structure of a few nanometers in size, is made up of hundreds to thousands of atoms, and has a quantum confinement effect in which an energy band gap is increased due to the small size thereof. When light with a wavelength having a higher energy than the band gap is incident to the quantum dot, the quantum dot absorbs the light and becomes in an excited state, and then drops to the ground state by emitting light with a particular wavelength. The emitted light with the particular wavelength has a value corresponding to the band gap. The quantum dot may control light-emitting characteristics due to the quantum confinement effect by controlling the size and composition thereof.

A core of the quantum dot may be selected from among a Group II-VI compound, a Group I-II-VI compound, a Group II-IV-VI compound, a Group I-II-IV-VI compound, a Group III-VI compound, a Group I-III-VI compound, a Group III-V compound, a Group III-II-V compound, a Group II-IV-V compound, a Group IV-VI compound, a Group IV element, a Group IV compound, and a combination thereof.

The Group II-VI compound may be selected from the group consisting of: a binary compound selected from the group consisting of CdS, CdSe, CdTe, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of CdZnSeS, CdZnSeTe, CdZnSTe, CdHgSeS, CdHgSeTe, CdHgSTe, HgZnSeS, HgZnSeTe, HgZnSTe, and a mixture thereof. Meanwhile, the Group II-VI compound may further include a Group I metal and/or a Group IV element. The Group I-II-VI compound may be selected from CuSnS or CuZnS, the Group II-IV-VI compound may be selected from ZnSnS or the like. The Group I-II-IV-VI compound may be selected from a quaternary compound selected from the group consisting of Cu₂ZnSnS₂, Cu₂ZnSnS₄, Cu₂ZnSnSe₄, Ag₂ZnSnS₂, and a mixture thereof.

The Group III-VI compound may include: a binary compound such as In₂S₃ and In₂Se₃; a ternary compound such as InGaS₃ and InGaSe₃; or a random combination thereof.

The Group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO₂, and a mixture thereof, or a quaternary compound such as AgInGaS₂ and CuInGaS₂.

The Group III-V compound may be selected from the group consisting of: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. Meanwhile, the Group III-V compound may further include a Group II metal. For example, InZnP and the like may be selected as a Group III-II-V compound.

The Group II-IV-V compound may be a ternary compound selected from the group consisting of ZnSnP, ZnSnP₂, ZnSnAs₂, ZnGeP₂, ZnGeAs₂, CdSnP₂, CdGeP₂, and a mixture thereof.

The Group IV-VI compound may be selected from the group consisting of: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; and a quaternary compound selected from the group consisting of SnPbSSe, SnPbSeTe, SnPbSTe, a mixture thereof. The Group IV element may be selected from the group consisting of Si, Ge, and a mixture thereof. The Group IV compound may be a binary compound selected from the group consisting of SiC, SiGe, and a mixture thereof.

At this time, the binary compound, the ternary compound, or the quaternary compound may be present in uniform concentration in a particle, or may be present in one particle while having partially different concentration distributions. In addition, the quantum dot may have a core/shell structure in which one quantum dot surrounds another quantum dot. In the core/shell structure, the quantum dot may have a concentration gradient in which the concentration of an element existing in the shell gradually decreases toward the core.

In some embodiments, the quantum dot may have a core-shell structure including a core having the aforementioned nanocrystal and a shell surrounding the core. The shell of the quantum dot may serve as a protective layer for preventing chemical modification of the core to maintain semiconductor characteristics, and/or may serve as a charging layer for imparting electrophoretic characteristics to the quantum dot. The shell may be a single layer or multiple layers. The shell of the quantum dot may be, for example, a metal or nonmetal oxide, a semiconductor compound, or a combination thereof.

For example, examples of the metal or nonmetal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO, or a ternary compound such as MgAl₂O₄, CoFe₂O₄, NiFe₂O₄, and CoMn₂O₄, but an embodiment of the inventive concept is not limited thereto.

In addition, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and AlSb, but an embodiment of the inventive concept is not limited thereto.

The quantum dot may have a full width of half maximum (FWHM) of an emission wavelength spectrum of about 45 nm or less, desirably about 40 nm or less, and more desirably about 30 nm or less. In this range, color purity or color reproducibility may be improved. Moreover, light emitted through such quantum dots is emitted in all directions, thereby improving the viewing angle of light.

In addition, the form of the quantum dot is a form commonly used in the art, and is not particularly limited. More specifically, however, the quantum dot may have a spherical, pyramidal, or multi-armed form, or have the form of cubic nanoparticles, nanotubes, nanowires, nanofibers, nanoplate particles, or the like.

The quantum dot may control colors of emitted light according to the size of a particle, and accordingly, the quantum dot may have various light-emitting colors such as blue, red, and green.

The third insulation layer 200-3 may cover the partition walls BW, the first light conversion pattern CCF-R, the second light conversion pattern CCF-G, and the transparent resin pattern SP. For example, the third insulation layer 200-3 may be an inorganic layer.

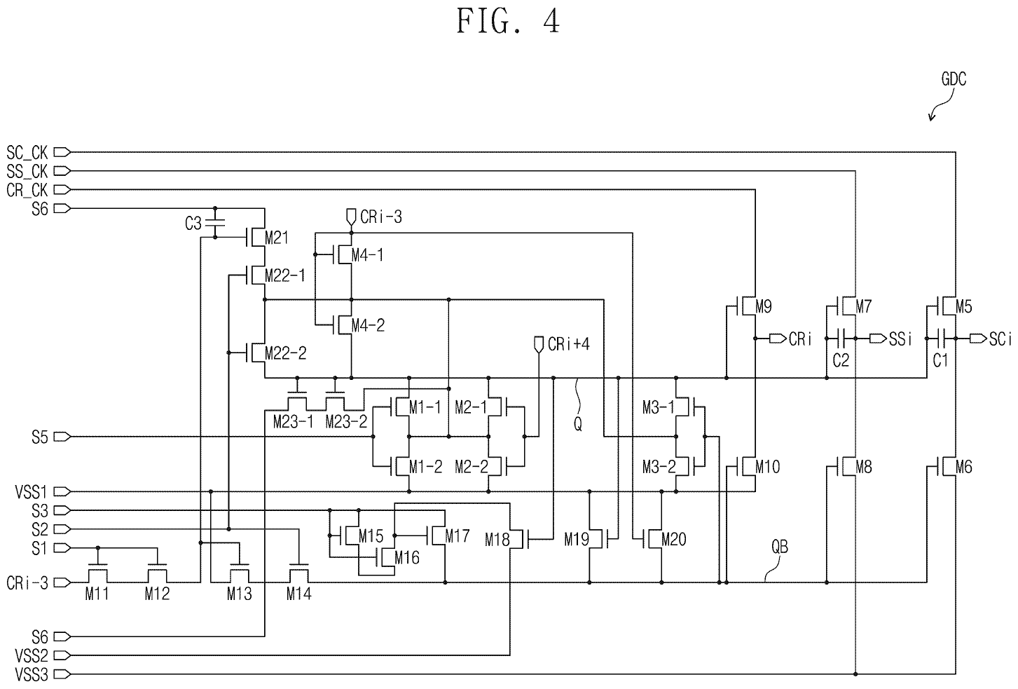

FIG. 4 is an equivalent circuit diagram of a gate driving circuit GDC according to an embodiment of the inventive concept.

FIG. 4 illustrates a portion of the gate driving circuit GDC that outputs an ith first scan signal SCi and an ith second scan signal SSi. Here, i refers to a natural number of 1 to m. For example, the gate driving circuit GDC may include a plurality of stages, and FIG. 4 may be an equivalent circuit diagram of one stage of the plurality of stages. The gate driving circuit GDC may include entire circuit components (for example, at least m stages) for outputting the first scan signals SC1 through SCm and the second scan signals SS1 through SSm.

The circuit illustrated in FIG. 4 is only an example of the gate driving circuit GDC, and the configuration of the gate driving circuit GDC may be variously changed.

Referring to FIG. 4, the gate driving circuit GDC may receive clock signals SC_CK, SS_CK, and CR_CK, switching signals S1 through S6, carry signals CRi−3 and CRi+4, a first low voltage VSS1, a second low voltage VSS2, and a third low voltage VSS3, and may output a first scan signal SCi, a second scan signal SSi, and a carry signal CRi. The carry signals CRi−3 and CRi+4 may be signals generated inside the gate driving circuit GDC. That is, an (i−3)-th carry signal CRi−3 may be related to an (i−3)-th first scan signal SCi−3 and an (i−3)-th second scan signal SSi−3, and an (i+4)-th carry signal CRi+4 may be related to an (i+4)-th first scan signal SCi+4 and an (i+4)-th second scan signal SSi+4.

The gate driving circuit GDC may include transistors M1-1, M1-2, M2-2, M2-2, M3-1, M3-2, M4-1, 4-2, M5, M6, M7, M8, M9, M10, M11, M12, M13, M14, M15, M16, M17, M18, M19, M20, M21, M22-1, M22-2, M23-1, M23-2, and M24, and capacitors C1, C2, and C3.

The switching signals S1 and S5 transition to a high level at the beginning of one frame, and are then maintained at a low level for the rest of the frame. Each of the switching signals S1 and S5 may be a signal indicating the beginning of one frame. One frame may include an active section and a blank section.

The switching signal S2 is maintained at a low level (for example, about −9V) during the active section, and transitions to a high level (for example, about 25V) at the beginning of the blank section. The switching signal S2 may be a signal indicating the beginning of the blank section.

The switching signal S3 is maintained at a high level (for example, about 25V) or at a low level (for example, about −9V) during one frame.

The switching signal S6 is a signal that is maintained at a high level (for example, about 25V).

The gate driving circuit GDC illustrated in FIG. 4 operates as follows.

When the switching signal S5 transitions to a high level at the beginning of one frame, transistors M1-1 and M1-2 are turned on, and a first node Q is initialized to a first low voltage VSS1.

Since transistors M15, M16, and M17 are in a turn-on state while the switching signal S3 is at a high level (for example, about 25V), a second node QB may be set to a high level corresponding to the switching signal S3.

When the carry signal CRi−3 transitions to a high level, transistors M4-1 and M4-2 may be turned on, and the first node Q may transition to a high level. If the clock signals SC_CK, SS_CK, and CR_CK are at a high level when the first node Q transitions to a high level, transistors M5, M7, and M9 may be turned on, and thus the first scan signal SCi, the second scan signal SSi, and the carry signal CRi may each transition to a high level. Meanwhile, when the carry signal CRi−3 transitions to a high level, a transistor M20 may be turned on, and the second node QB may be discharged to the first voltage VSS1.

The transistors M5, M7, and M9 are transistors which control output of the signal SCi or SSi provided to the light-emitting elements OLED (see FIG. 3B), or which control the carry signal CRi provided to the next stage, and may be referred to as switching transistors M5, M7, and M9. The channel widths of the switching transistors M5, M7, and M9 may be greater than the channel widths of the remaining transistors M1-1, M1-2, M2-2, M2-2, M3-1, M3-2, M4-1, 4-2, M6, M8, M10, M11, M12, M13, M14, M15, M16, M17, M18, M19, M20, M21, M22-1, M22-2, M23-1, M23-2, and M24.

Meanwhile, since the transistor M19 is turned on while the first node Q is at a high level, the second node QB may be maintained at the first voltage VSS1, that is, at a low level. Therefore, transistors M6, M8, and M10 may be maintained to be in a turn-off state.

When the clock signals SC_CK, SS_CK, and CR_CR are each changed from a high level to a low level, each of the first scan signal SCi, the second scan signal SSi, and the carry signal CRi transitions from a high level to a low level.

In succession, when the carry signal CRi+4 transitions to a high level, transistors M2-1 and M2-2 may be turned on, and the first node Q may be discharged to the first low voltage VSS1.

When the first node Q is at the first low voltage VSS1, and a carry signal CRi−3 is at a low level, the transistors M19 and M20 may each be turned off, and the second node QB may be maintained at a high level corresponding to a third switching signal V3. When the second node QB is at a high level, the transistors M6, M8, and M10 are turned on, and thus the first scan signal SCi, the second scan signal SSi, and the carry signal CRi may be maintained at a voltage level of the third low voltage VSS3. That is, the first scan signal SCi, the second scan signal SSi, and the carry signal CRi may be maintained at the third low voltage VSS3 during a blank section BP of one frame F.

The gate driving circuit GDC may include at least one transistor having a double-gate structure to be described later according to an embodiment of the inventive concept. In particular, at least one of the switching transistors M5, M7, and M9 that control output of signals provided to the light-emitting elements may have the double-gate structure to be described later according to an embodiment of the inventive concept.

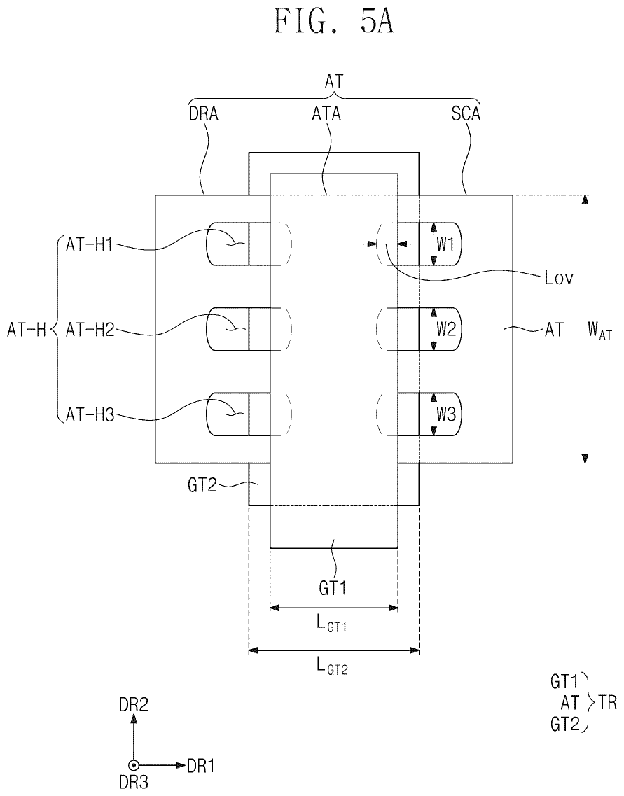

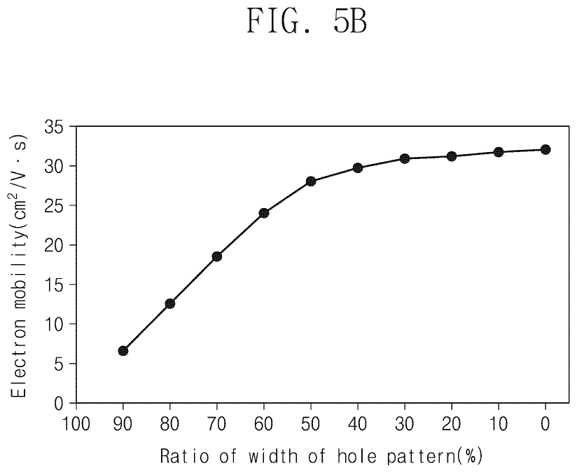

FIG. 5A is a plan view schematically illustrating a transistor TR according to an embodiment of the inventive concept. FIG. 5B is a graph showing electron mobility of a transistor TR according to an embodiment of the inventive concept.

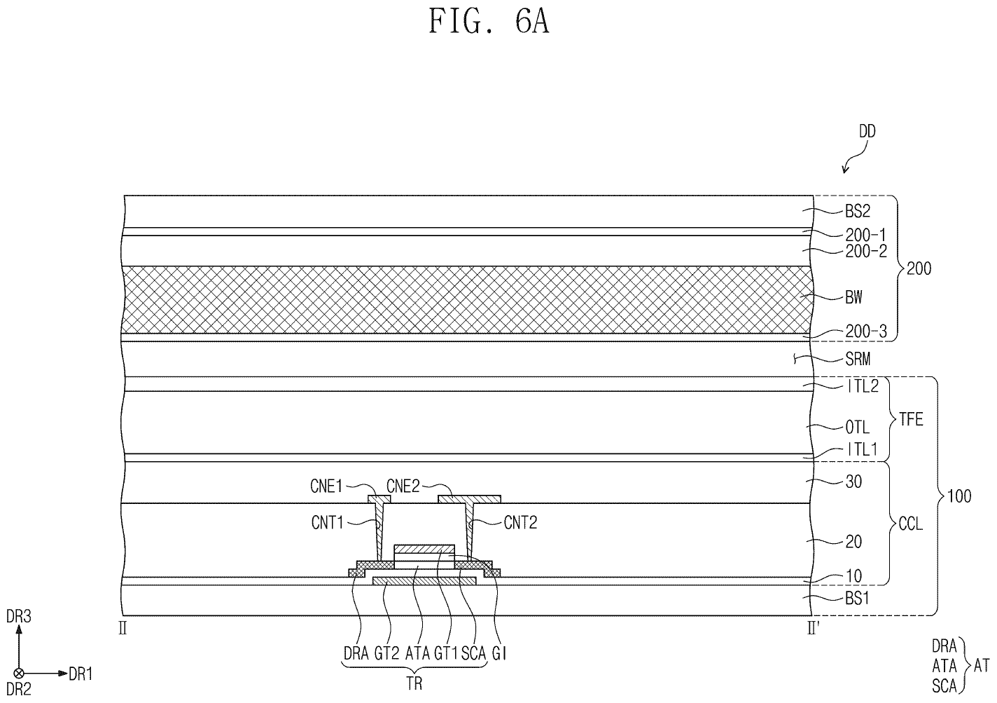

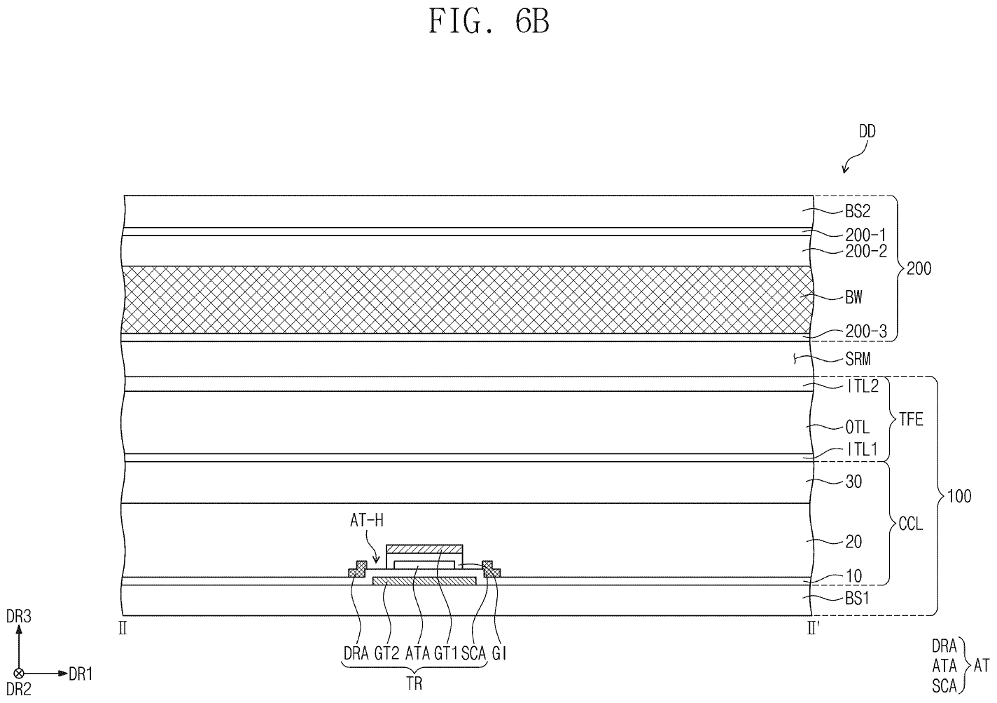

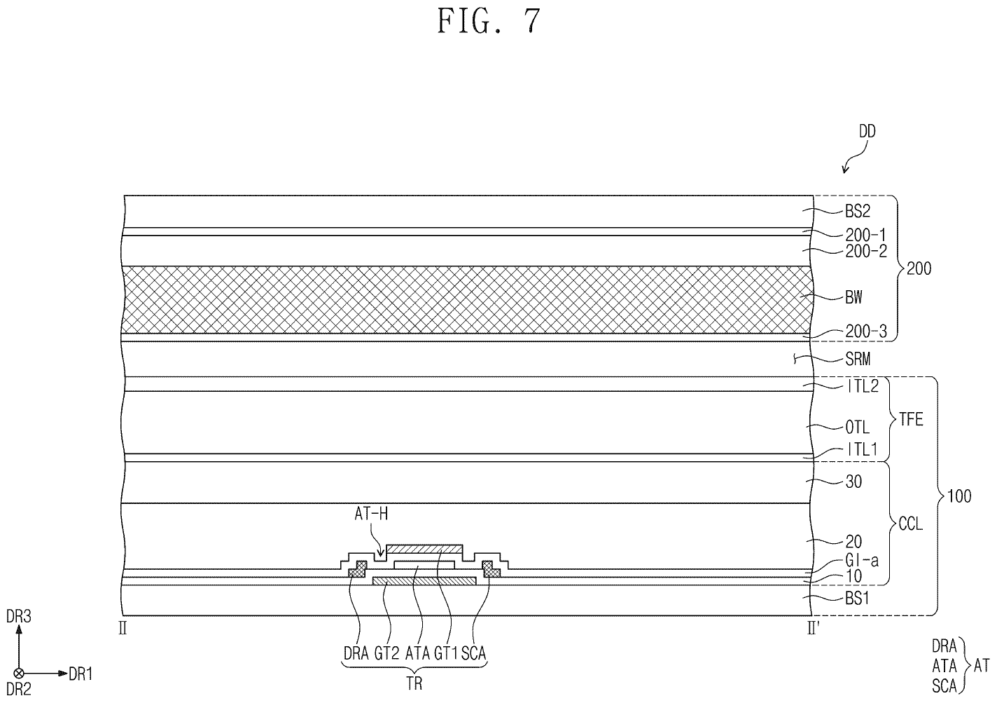

Referring to FIG. 5A, a transistor TR according to an embodiment of the inventive concept may include a first electrode GT1, an active layer AT disposed under the first electrode GT1, a second electrode GT2 disposed under the active layer AT. A planar arrangement relationship is described with reference to FIG. 5A, and a vertical arrangement relationship will be described later in detail with reference to FIGS. 6A and 7.

The active layer AT may include a source region SCA, a drain region DRA, and an active region ATA. The source region SCA and the drain region DRA may be regions not overlapping the first electrode GT1 on a plane. In addition, the active region ATA may be a region overlapping the first electrode GT1 on a plane.

As illustrated in FIG. 5A, the drain region DRA, the active region ATA, and the source region SCA may be arranged in sequence along a first direction DR1. FIG. 5A illustrates the drain region DRA and the source region SCA as an example, and the positions thereof may be swapped according to voltages applied thereto.

The second electrode GT2 may be disposed overlapping at least a portion of the active layer AT. Accordingly, electron mobility of the transistor TR may increase, compared to the case where only the first electrode GT1 is disposed. Accordingly, it may be possible to reduce the length of the transistor TR in the first direction DR1 while providing the same amount of current. Therefore, by including the gate driving circuit GDC (see FIG. 1C) having the transistor TR according to an embodiment of the inventive concept, it may be possible to achieve the display panel 100 (see FIG. 1A) having a narrow bezel.

As illustrated in FIG. 5A, the active layer AT may include a hole pattern AT-H. The hole pattern AT-H may include one or more through-holes characterized by absence of the active layer material, extending through the thickness of active layer AT. The hole pattern AT-H may be formed through a photoresist process. FIG. 5A exemplarily illustrates that the hole pattern AT-H includes three holes AT-H1, AT-H2, and AT-H3 provided on each of the left and right sides. However, the number of holes included in the hole pattern AT-H is not limited thereto, and may be variously changed according to the conditions of the transistor TR and the process conditions.

The hole pattern AT-H may extend into a portion of the source region SCA and the drain region DRA. Due to the presence of the hole pattern AT-H, the area of a region where the source region SCA and the drain region DRA overlap the second electrode GT2 is reduced. This may lead to a reduction in parasitic capacitance, which may be generated due to the second electrode GT2 overlapping the source region SCA and the drain region DRA.

Referring to FIG. 5A, the second electrode GT2 may have a length L_{GT2} greater than a length L_{GT1} of the first electrode GT1 in a first direction DR1. The length L_{GT1} of the first electrode GT1 in the first direction DR1 may be about 4 μm to about 10 μm, and the length L_{GT2} of the second electrode GT2 in the first direction DR1 may be greater than the length L_{GT1} by about 2 μm through about 3 μm. For example, the length L_{GT1} of the first electrode GT1 in the first direction DR1 may be about 4 μm, and the length L_{GT2} of the second electrode GT2 in the first direction DR1 may be greater than the length L_{GT1} by about 2 μm through about 3 μm. Accordingly, it may be possible to achieve sufficient effect of increasing electron mobility by employing a double-gate structure of the first electrode GT1 and the second electrode GT2. As used herein, “length” refers to measurement in the first direction DR1 and “width” refers to measurement in the second direction DR2.

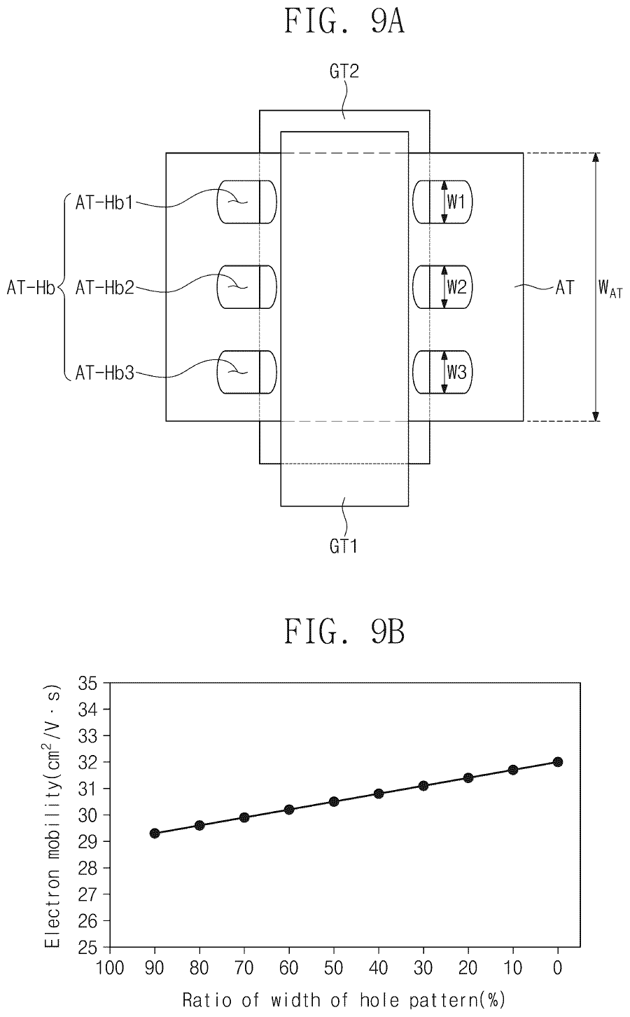

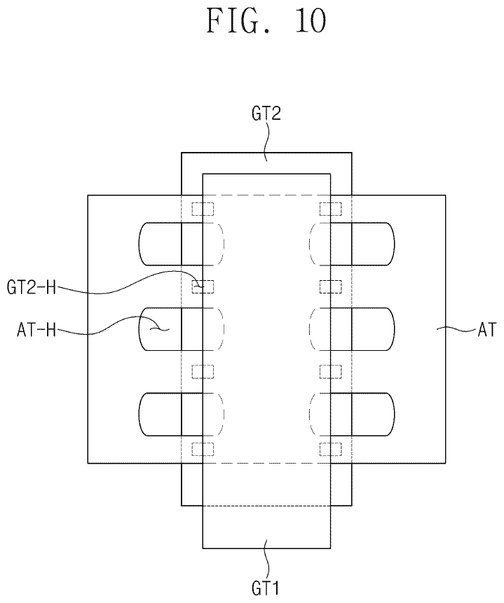

Meanwhile, the hole pattern AT-H may partially overlap the first electrode GT1, such that less than all of the hole pattern AT-H overlaps the first electrode GT1. The overlap length L_{OV} of the one portion of the hole pattern AT-H overlapping the first electrode GT1 in the first direction DR1 may be less than or equal to about 4 μm. For example, when the length L_{GT1} of the first electrode GT1 in the first direction DR1 is about 4 μm, the overlap length L_{OV} of the one portion of the hole pattern AT-H overlapping the first electrode GT1 in the first direction DR1 may be less than or equal to about 1 μm. In the above range, it may be possible to achieve more excellent electron mobility while reducing parasitic capacitance. In FIG. 5A, a portion of the hole pattern AT-H overlapping the first electrode GT1 is illustrated in dotted lines, and a portion of the hole pattern AT-H not overlapping the first electrode GT1 is illustrated in solid lines. However, the planar arrangement of the hole pattern AT-H is not limited thereto, and another example of the arrangement will be described with reference to FIG. 9A.

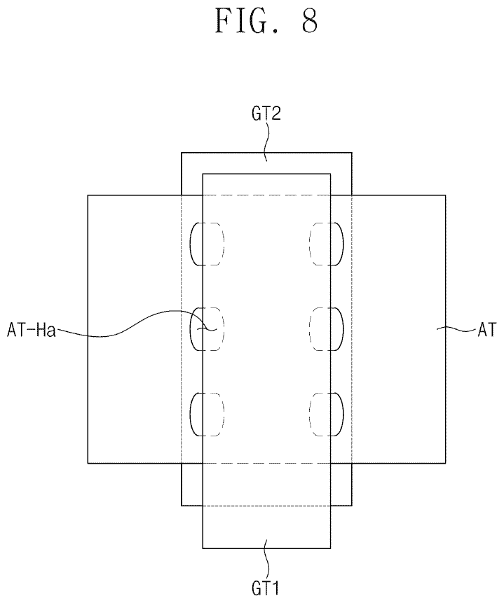

In addition, one portion of the hole pattern AT-H may overlap the second electrode GT2, and another portion thereof may not overlap the second electrode GT2. However, the planar arrangement of the hole pattern AT-H is not limited thereto, and another example of the arrangement will be described with reference to FIG. 8.

When the hole pattern AT-H has the planar arrangement as in FIG. 5A, electron mobility increasing effect may become greater as the area of a portion where the hole pattern AT-H overlaps the first and second electrodes GT1 and GT2 is smaller. The hole pattern AT-H may include a plurality of holes AT-H1, AT-H2, and AT-H3. The plurality of holes AT-H1, AT-H2, and AT-H3 may have predetermined widths W1, W2, and W3, respectively. The predetermined widths W1, W2, and W3 of the plurality of holes AT-H1, AT-H2, and AT-H3 may be same as, or different from each other. FIG. 5B is a graph showing electron mobility versus the ratio of the sum W1+W2+W3 of the widths W1, W2, and W3 of the holes AT-H1, AT-H2, and AT-H3 to the width WAT of the active layer AT.

In particular, FIG. 5B exemplarily illustrates electron mobility in the case where a portion of the hole pattern AT-H overlapping the first electrode GT1 (i.e., L_{OV} of AT-H1) has a length of at most about 1 μm in the first direction DR1. When the ratio of the widths W1+W2+W3 of the hole pattern AT-H to the width WAT of the active layer AT (that is, the ratio of the sum W1+W2+W3 of the widths W1, W2, and W3 of the holes AT-H1, AT-H2, and AT-H3 to the width WAT of the active layer AT) is less than or equal to about 40%, it may be possible to achieve more excellent electron mobility while reducing the parasitic capacitance.

FIG. 6A is a cross-sectional view illustrating a non-display region of a display device DD according to an embodiment of the inventive concept. FIG. 6B is a cross-sectional view illustrating a non-display region of a display device DD according to an embodiment of the inventive concept.

FIGS. 6A and 6B are exemplary cross-sectional views, taken along line II-II′ of FIG. 1C, each illustrating a non-display region of a display device DD including the transistor TR having a double-gate structure previously described with reference to FIG. 5A. In particular, in the transistor TR of FIG. 5A, FIG. 6A is an exemplary cross-sectional view of a portion of the non-display region where a hole pattern AT-H is not disposed, and FIG. 6B is an exemplary cross-sectional view of a portion of the non-display region where the hole pattern AT-H is disposed. Referring to FIG. 6A, as previously described with reference to FIG. 5A, the transistor TR according to an embodiment of the inventive concept may include a first electrode GT1, an active layer AT disposed under the first electrode GT1, and a second electrode GT2 disposed under the active layer AT. The transistor TR may further include a gate insulation layer GI for insulating the active layer AT and the first electrode GT1.

Moreover, the active layer AT may include a source region SCA, a drain region DRA, and an active region ATA. The source region SCA and the drain region DRA may be regions not overlapping the first electrode GT1 on a plane. In addition, the active region ATA may be a region overlapping the first electrode GT1 on a plane.

The drain region DRA and the source region SCA may be respectively connected to a first connecting electrode CNE1 and a second connecting electrode CNE2 through contact holes CNT1 and CNT2 passing through a second insulation layer 20. In addition, the first electrode GT1 and the second electrode GT2 may be electrically connected to each other, and may thus have a same voltage applied thereto. Accordingly, as previously described, electron mobility may be increased, compared to the case where only the first electrode GT1 is disposed. That is, it may be possible to reduce the length of the transistor TR in a first direction DR1 while providing the same amount of current, thereby achieving a display panel 100 having a narrow bezel.

Referring to FIG. 6B, the active layer AT includes a hole pattern AT-H, and thus it may be possible to reduce the area of a region where the source region SCA and the drain region DRA overlap the second electrode GT2. This may lead to a reduction in parasitic capacitance that may be generated due to the second electrode GT2 overlapping the source region SCA and the drain region DRA.

In addition, in regard to a display panel 100, a synthetic resin material SRM, and a light conversion panel 200, the contents previously described with reference to FIG. 3B may be similarly applied.

FIG. 7 is a cross-sectional view illustrating a non-display region of a display device DD according to an embodiment of the inventive concept.

Referring to FIG. 7, a gate insulation layer GI-a may be disposed above a first insulation layer 10, and cover an active layer AT. Unlike what is illustrated in FIG. 6A, the gate insulation layer GI-a may also be disposed in a region where the gate insulation layer GI-a does not overlap a first electrode GT1. In addition, a portion of the gate insulation layer GI-a may also be disposed in a hole pattern AT-H.

FIG. 8 is a plan view schematically illustrating a transistor TR according to an embodiment of the inventive concept.

Referring to FIG. 8, in a transistor TR according to an embodiment, a hole pattern AT-Ha, unlike what is illustrated in FIG. 5A, may be disposed overlapping a second electrode GT2. That is, the hole pattern AT-Ha may not be disposed at a location not overlapping a second electrode GT2. In FIG. 8, a portion of the hole pattern AT-Ha overlapping the first electrode GT1 is illustrated in broken lines, and a portion of the hole pattern AT-Ha not overlapping the first electrode GT1 is illustrated in solid lines.

FIG. 9A is a plan view schematically illustrating a transistor TR according to an embodiment of the inventive concept. FIG. 9B is a graph showing electron mobility of a transistor TR according to an embodiment of the inventive concept.

Referring to FIG. 9A, in a transistor TR according to an embodiment, a hole pattern AT-Hb may be disposed at a location not overlapping a first electrode GT1. That is, the hole pattern AT-Hb, unlike what is illustrated in FIG. 5A, may not be disposed at a location overlapping the first electrode GT1. In FIG. 9A, the hole pattern AT-Hb is illustrated in solid lines as the hole pattern AT-Hb does not overlap the first electrode GT1.

When the hole pattern AT-Hb has the planar arrangement as in FIG. 9A, electron mobility increasing effect may become greater as the area of a portion where the hole pattern AT-Hb overlaps the second electrode GT2 is smaller.

The hole pattern AT-Hb may include a plurality of holes AT-Hb1, AT-Hb2, and AT-Hb3. The plurality of holes AT-Hb1, AT-Hb2, and AT-Hb3 may have predetermined widths W1, W2, and W3, respectively. FIG. 9B is a graph showing electron mobility versus the ratio of the sum W1+W2+W3 of the widths W1, W2, and W3 of the holes AT-Hb1, AT-Hb2, and AT-Hb3 to the width WAT of the active layer AT illustrated in FIG. 9A. When the ratio of the widths W1+W2+W3 of the hole pattern to the width WAT of the active layer AT is less than or equal to about 80%, it may be possible to achieve more excellent electron mobility while reducing parasitic capacitance.

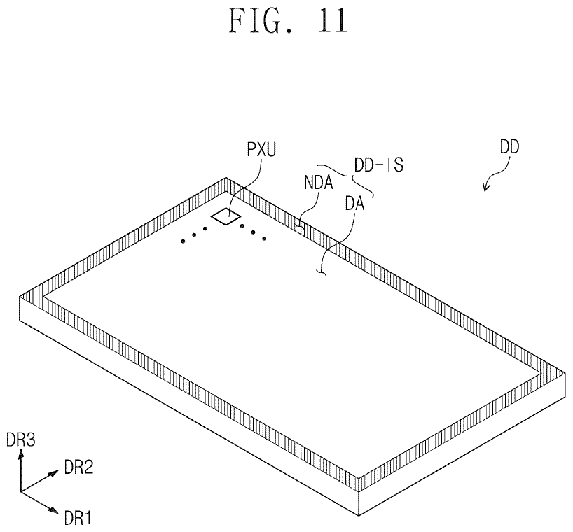

FIG. 10 is a plan view schematically illustrating a transistor TR according to an embodiment of the inventive concept.

Referring to FIG. 10, a transistor TR according to an embodiment may include a hole pattern AT-H in an active layer AT, and also, may further include a hole pattern GT2-H in a second electrode GT2. Accordingly, it may be possible to further reduce the area of a portion where the second electrode GT2 overlaps the source region SCA (see FIG. 5A) and the drain region DRA (see FIG. 5A), thereby further reducing parasitic capacitance.

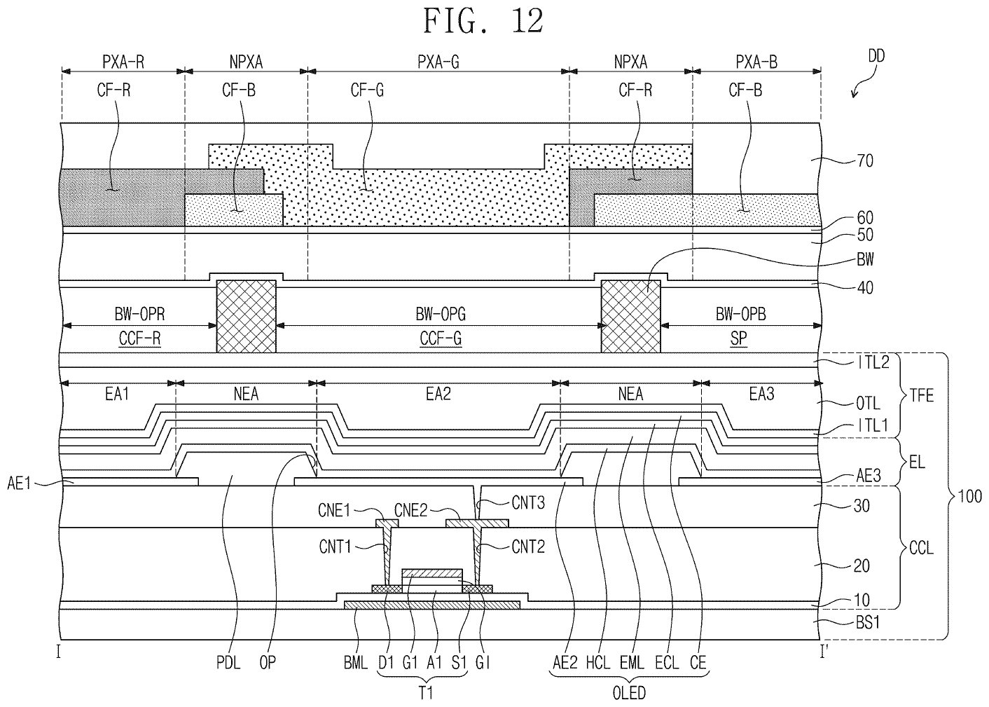

FIG. 11 is a perspective view of a display device DD according to an embodiment of the inventive concept. FIG. 12 is a cross-sectional view illustrating a display region DA of a display device DD according to an embodiment of the inventive concept.

Hereinafter, detailed description of the same configuration as the configuration described with reference to FIGS. 1A through 4 will be omitted.

A display device DD according to this embodiment includes a single base layer BS1, unlike the display device DD described with reference to FIGS. 1A through 4. In a manufacturing process, an attachment process for a display panel 100 and a light conversion panel 200 is omitted, and structures are formed in sequence on the base layer BS1.

Referring to FIGS. 11 and 12, the display device DD includes the same display panel 100 as what is illustrated in FIG. 3B. Partition walls BW are disposed on a thin-film encapsulation layer TFE. A first light conversion pattern CCF-R, a second light conversion pattern CCF-G, and a transparent resin pattern SP are disposed respectively in openings BW-OPR, BW-OPG, and BW-OPB of the partition walls BW. A fourth insulation layer 40 may cover the partition walls BW, the first light conversion pattern CCF-R, the second light conversion pattern CCF-G, and the transparent resin pattern SP. For example, the fourth insulation layer 40 may be an inorganic film.

A fifth insulation layer 50 is disposed on the fourth insulation layer 40. The fifth insulation layer 50 may have a lower refractive index than the fourth insulation layer 40. The fifth insulation layer 50 may have a refractive index of about 1.1 to about 1.5. The refractive index of the fifth insulation layer 50 may be controlled according to the ratio of hollow inorganic particles, and/or voids, etc. included in the fifth insulation layer 50. The fifth insulation layer 50 may provide source light and the converted light more vertically.

A sixth insulation layer 60 is disposed on the fifth insulation layer 50. The sixth insulation layer 60 may be an inorganic layer that seals the structures thereunder. The sixth insulation layer 60 may be also omitted.

A first color filer CF-R, a second color filter CF-G, and a third color filter CF-B are disposed on the sixth insulation layer 60. A seventh insulation layer 70 may be disposed on the first color filter CF-R, the second color filter CF-G, and the third color filter CF-B, and the seventh insulation layer 70 may provide a flat surface while covering the first color filter CF-R, the second color filter CF-G, and the third color filter CF-B. The seventh insulation layer 70 may be an organic film.

According to what is previously described, a transistor according to an embodiment of the inventive concept has a double-gate structure, thereby making it possible to reduce the area of the transistor, and the transistor includes a hole pattern in an active layer, thereby making it possible to reduce parasitic capacitance.

Moreover, since a display panel according to an embodiment of the inventive concept includes the above-mentioned transistor, a dead space of the display panel may be reduced, and accordingly a display panel having a narrow bezel may be achieved.

Although the embodiments of the inventive concept have been described, it is understood that the inventive concept should not be limited to these embodiments but various changes and modifications can be made by one ordinary skilled in the art within the spirit and scope of the inventive concept as hereinafter claimed.

Therefore, the technical scope of the inventive concept should not be limited to the contents described in the detailed description of the specification, but should be defined by the claims.

What is claimed is:

1. A transistor comprising:
a first electrode;
an active layer disposed under the first electrode and including a source region, a drain region, and an active region overlapping the first electrode on a plane; and
a second electrode disposed under the active layer and overlapping at least a portion of the active layer on a plane;
wherein the active layer includes a hole pattern, and the hole pattern overlaps at least a portion of the source region and a portion of the drain region on a plane.

2. The transistor of claim 1, wherein the drain region, the active region, and the source region are sequentially arranged along a first direction, and
a length of the second electrode in the first direction is greater than a length of the first electrode in the first direction.

3. The transistor of claim 1, wherein the hole pattern partially overlaps the first electrode.

4. The transistor of claim 3, wherein the drain region, the active region, and the source region are sequentially arranged along a first direction,
a length of the first electrode in the first direction is about 4 μm to about 10 μm, and
an overlap length of the hole pattern overlapping the first electrode is equal to or less than about 4 μm measured in the first direction.

5. The transistor of claim 4, wherein the overlap length of the hole pattern overlapping the first electrode is equal to or less than about 1 μm measured along the first direction.

6. The transistor of claim 3, wherein the hole pattern comprises a plurality of holes, and
a ratio of sum of widths of the plurality of holes to a width of the active layer is no more than about 40%.

7. The transistor of claim 1, wherein the hole pattern is in the part of the active layer that does not overlap the first electrode.

8. The transistor of claim 7, wherein the hole pattern comprises a plurality of holes, and
a ratio of sum of widths of the plurality of holes to a width of the active layer is no more than about 80%.

9. The transistor of claim 1, wherein the hole pattern partially overlaps the second electrode.

10. The transistor of claim 1, wherein the hole pattern overlaps the second electrode.

11. The transistor of claim 1, wherein the first electrode and the second electrode are electrically connected to each other and receive a same voltage.

12. The transistor of claim 1, wherein the active layer comprises an oxide semiconductor.

13. A display panel comprising:
a base layer;
a circuit layer disposed on the base layer and including a gate driving circuit; and
a light-emitting layer disposed on the circuit layer,
wherein the gate driving circuit includes a plurality of transistors, and
at least one of the plurality of transistors includes
a first electrode,
an active layer disposed under the first electrode and including a hole pattern, and
a second electrode disposed under the active layer and overlapping at least a portion of the active layer on a plane.

14. The display panel of claim 13, wherein the active layer comprises a source region, a drain region, and an active region overlapping the first electrode on a plane,
the drain region, the active region, and the source region are sequentially arranged along a first direction, and
a length of the second electrode in the first direction is greater than a length of the first electrode in the first direction.

15. The display panel of claim 14, wherein the hole pattern overlaps at least a portion of the source region and a portion of the drain region on a plane.

16. The display panel of claim 13, wherein on a plane, one portion of the hole pattern overlaps the first electrode.

17. The display panel of claim 16, wherein the active layer comprises a source region, a drain region, and an active region, wherein the active region overlaps the first electrode,
the drain region, the active region, and the source region are sequentially arranged along a first direction,
a length of the first electrode in the first direction is about 4 μm to about 10 μm, and
an overlap length of the hole pattern overlapping the first electrode is equal to or less than about 4 μm measured in the first direction.

18. The display panel of claim 13, wherein the hole pattern partially overlaps the second electrode.

19. The display panel of claim 13, wherein the hole pattern does not overlap the first electrode.

20. The display panel of claim 13, wherein the hole pattern overlaps the second electrode.

21. The display panel of claim 13, wherein the first electrode and the second electrode are electrically connected to each other and receive a same voltage.
